(19) United States
(12) Patent Application Publication
(10) Pub. No.: US 2025/0006543 A1
(43) Pub. Date: Jan. 2, 2025

(54) METHOD FOR PRODUCING AN OPTOELECTRONIC ASSEMBLY

(71) Applicant: ams-OSRAM International GmbH, Regensburg (DE)

(72) Inventors: Daniel Leisen, Regensburg (DE); Ingo Neudecker, Regensburg (DE); Herbert Brunner, Sinzing (DE)

(21) Appl. No.: 18/576,339

(22) PCT Filed: Jul. 20, 2022
(86) PCT No.: PCT/EP2022/070343

§ 371 Date: Jan. 3, 2024

(30) Foreign Application Priority Data
Aug. 3, 2021 (DE) 10 2021 120 136.5

(51) Int. Cl. H01L 21/683; H01L 33/48; H01L 33/58; H01L 33/60; H01L 33/62

(52) U.S. Cl. CPC H01L 21/6835; H01L 33/486; H01L 33/58; H01L 33/60; H01L 33/62; H01L 2221/68354; H01L 2221/68368; H01L 2221/68381; H01L 2933/0058; H01L 2933/0066

(57) ABSTRACT

In an embodiment a method for producing an optoelectronic assembly includes providing at least one component of the optoelectronic assembly, providing a source carrier with a functional material on a lower face of the source carrier facing the at least one component, detaching a part of the functional material by irradiation via a laser beam through an upper face of the source carrier facing away from the at least one component, attaching the detached part of the functional material to a side of the at least one component facing the source carrier and completing the optoelectronic assembly, wherein the source carrier comprises cavities, each cavity being filled with the functional material.

### CROSS-REFERENCE TO RELATED APPLICATIONS

This patent application is a national phase filing under section 371 of PCT/EP2022/070343, filed Jul. 20, 2022, which claims the priority of German patent application 102021120136.5, filed Aug. 3, 2021, each of which is incorporated herein by reference in its entirety.

### TECHNICAL FIELD

A method for producing an optoelectronic assembly is disclosed.

### SUMMARY

Embodiments provide a method for producing an optoelectronic assembly which is particularly versatile.

According to at least one embodiment of the method for producing an optoelectronic assembly, at least one component of the optoelectronic assembly is first provided.

The component may, for example, be a connection carrier such as a printed circuit board or a lead frame. It can also be a housing. Furthermore, it can be an optoelectronic semiconductor chip, which can be formed, for example, by a radiation-emitting semiconductor chip such as a light-emitting diode chip or a laser diode chip, or by a radiation-receiving semiconductor chip such as, for example, a photodiode chip. Furthermore, the component may, for example, be a potting compound for such a semiconductor chip, which encapsulates the semiconductor chip at least in places in a form-fitting manner.

In the method, at least one component is provided. It is also possible that two or more components are provided and the subsequent process steps are then carried out on one or more of the components provided.

According to at least one embodiment of the method, a source carrier is provided which comprises a lower face which is provided with a functional material. The functional material is a material that performs a function in the optoelectronic assembly to be produced.

The functional material can, for example, be an optically functional material that performs an optical function in the assembly. The functional material may, for example, be a radiation-reflecting material. The radiation-reflecting material can be configured to reflect, in particular visible, light. For example, the radiation-reflecting material may comprise a reflectivity of at least 85% for electromagnetic radiation of the visible region. The radiation-reflecting material can be configured to reflect electromagnetic radiation and/or ambient light generated or to be received in the optoelectronic component during operation. For example, the radiation-reflecting material comprises a matrix material in which radiation-scattering or radiation-reflecting particles, which can be formed with titanium dioxide, for example, are incorporated. The functional material can then appear white.

Additionally or alternatively, it is possible that the functional material is a radiation-absorbing material. The radiation-absorbing material may be a material that absorbs at least 85% of visible light. For example, the radiation-absorbing material may be configured to absorb ambient light and/or light generated or to be received in the optoelectronic device. In particular, the radiation-absorbing material may comprise a black color and be formed with a matrix material into which radiation-absorbing particles such as carbon black are introduced.

Alternatively or additionally, the functional material can be a radiation-scattering material that is configured to scatter electromagnetic radiation, in particular visible light. The radiation-scattering material can, for example, be configured to scatter ambient light and/or light generated or to be received in the optoelectronic device.

Alternatively or additionally, the functional material may comprise a radiation-refracting material that is configured to refract electromagnetic radiation, in particular visible light. The radiation-refracting material can, for example, be used to form optical lenses. The radiation-refracting material is, for example, clear-sightedly transparent and/or comprises a refractive index of 1.3 or higher.

Alternatively or additionally, the functional material can be a sealing material that is provided as a protective coating and/or for closing openings in the optoelectronic device. The sealing material can, for example, be formed with a plastic and serve to reduce corrosion in the optoelectronic assembly.

Alternatively or additionally, the functional material may comprise an adhesive which is intended to bond components of the optoelectronic assembly together in a materially bonded manner. This means that the components are held together by the adhesive by atomic or molecular forces and form a non-detachable bond between the connected components, which can only be separated by destroying the layer formed from the adhesive.

The functional material is detachably attached to the source carrier. The functional material can be attached directly to the source carrier or one or more layers of other materials are arranged between the source carrier and the functional material. The functional material is arranged on a lower face of the source carrier facing the at least one component.

The source carrier is preferably formed with a radiation permeable material which is at least partially permeable to the electromagnetic radiation of a laser beam, by means of which the functional material is detached from the source carrier.

According to at least one embodiment, the method comprises a method step of detaching a part of the functional material by irradiating it by means of a laser beam through an upper face of the source carrier facing away from the at least one component.

During irradiation, for example, the functional material or a material between the source carrier and the functional material is heated. Due to the heating a part of the functional material or a material between the functional material and the source carrier can be liquified or transferred into the gas phase. Due to the transition to the gas phase an increase in volume can occur, which results in the functional material being separated from the source carrier in certain regions, for example by being blown off. Alternatively or additionally, due to the heating an adhesive force between the functional material and the source carrier can be reduced and the detachment of a part of the functional material then occurs, for example, due to gravity or because the adhesive force of the functional material to at least one component is greater than to the source carrier.

According to at least one embodiment of the method, attaching of the detached part of the functional material to a side of the at least one component facing the source carrier occurs. For example, after detaching the part of the functional material, an application of the functional material to the at least one component occurs due to a force such as gravity. Subsequently, attaching of the detached part can occur by curing the part of the functional material on the side of the at least one component facing the source carrier. Curing can occur, for example, by irradiation with UV radiation or thermally.

According to at least one embodiment of the method, finally, a completion of the optoelectronic assembly occurs. It is thereby possible that, after applying of the functional material to the at least one component, further method steps occur, in which it is also possible that further functional materials are applied to the same or other components of the optoelectronic assembly by the method described here. Furthermore, it is possible that the application of the functional material is the last method step and that the optoelectronic assembly is thus completed.

According to at least one embodiment, the method comprises the following steps, which are in particular carried out in the order indicated:
providing at least one component of the optoelectronic assembly,
providing a source carrier with a functional material on a lower face of the source carrier facing the at least one component,
detaching of a part of the functional material by irradiation by means of a laser beam through an upper face of the source carrier facing away from the at least one component,
attaching the detached part of the functional material to a side of the at least one component facing the source carrier,
completing the optoelectronic assembly.

The method described herein is based, among other things, on the consideration that by transferring a functional material from a source carrier, functional materials can be applied to different components of an optoelectronic assembly in a particularly versatile manner. In particular, the method makes it possible to apply different functional materials to different components of the optoelectronic assembly by carrying out the method several times on the same optoelectronic component. The method can thereby be used in different producing steps of an optoelectronic assembly. For example, the method can be used to apply an adhesive layer to an optoelectronic semiconductor chip, by means of which, for example, a cover body is attached to the semiconductor chip. Subsequently, the method can be used to apply a radiation-absorbing coating around the semiconductor chip, for example on an upper face of a connection carrier facing the semiconductor chip, to which the semiconductor chip is attached.

According to at least one embodiment of the method, a separating material, which is irradiated by means of the laser beam, is arranged between the source carrier and the functional material. The separating material is arranged on the lower face of the source carrier and can be in direct contact with the source carrier. It is also possible for the separating material to be in direct contact with the functional material. By irradiating the separating material by means of the laser beam, it is possible that an adhesive force between the separating material and the functional material is reduced to such an extent that the irradiated part of the functional material detaches from the source carrier due to gravity and moves towards the at least one component. Furthermore, it is possible for the separating material to be transferred at least in places into the liquid phase or the gas phase by irradiation with the laser beam and for the functional material to be detached in this way. The separating material can comprise radiation-absorbing components, for example particles, which are configured to absorb the laser radiation of the laser beam in a targeted manner, whereby heating and transfer of the separating material into the liquid or gaseous phase can be achieved in places. After detachment of the part of the functional material, residues of the separating material can remain on the source carrier.

According to at least one embodiment of the method, the functional material is formed as a layer or as a layer sequence comprising a main extension plane which runs parallel to a main extension plane of the source carrier. For example, the source carrier is in the form of a flat disk which comprises its laterally largest extension parallel to the main extension plane. Parallel to the main extension plane of the source carrier, the functional material is then applied directly to the source carrier or to the separating material as a layer or layer sequence comprising a main extension plane parallel to the main extension plane of the source carrier.

According to at least one embodiment of the method, the source carrier comprises cavities which are each filled with the same functional material or with different functional materials. This means that, in this embodiment, the source carrier is in particular not disc-shaped, but comprises in particular a plurality of cavities, for example of the same type, which are provided for receiving the functional material.

There can be a separating material between the functional material and the source carrier or the functional material may be in direct contact with the source carrier. Due to the shape of the cavities the shape of the functional material, which can be transferred to the at least one component when the functional material is detached from the source carrier, can be predetermined. This means that this method can, for example, be used to apply three-dimensional structures made of the functional material to the at least one component. In this way, structures such as optical lenses, for example, can be produced on the component from the functional material in a simple manner.

According to at least one embodiment of the method, regions between the cavities on the lower face of the source carrier facing the at least one component are free of functional material. This means that, in this embodiment, the source carrier is only covered on its lower face in places by functional material. The functional material can, for example, be arranged exclusively in cavities of the source carrier. In this way, it is particularly easy to selectively unhinge functional material from the cavities and apply it to the at least one component of the optoelectronic device.

According to at least one embodiment of the method, the functional material is in direct contact with the at least one component during detaching. In this way, the transfer from the functional material to the at least one component can take place with particular local precision, since an adjustment of the at least one component with respect to the source carrier can take place before the detaching and the part of the functional material that is detached is already in direct contact with the component during detaching.

Alternatively, it is possible that the functional material and the at least one component are arranged at a distance of at least 1 μm and/or at most 1500 μm from each other. In this case, a gap is thus arranged between the functional material and the at least one component. In this way, as little energy as possible, for example in the form of heat, is transferred to the component when the functional material is detached, so that it is also possible to coat particularly sensitive components by means of the functional material.

According to at least one embodiment of the method, the at least one component comprises an encapsulant surrounding a chip, wherein the functional material covers the encapsulant in places. The chip is, for example, an optoelectronic semiconductor chip which is configured to emit or receive electromagnetic radiation during operation of the optoelectronic device. The encapsulation can be molded onto the chip in places and surround it laterally and/or protrude vertically, for example. The functional material is applied to the encapsulation in such a way that the functional material covers the encapsulation in places. The functional material may, for example, be a material with an optical function such as a radiation-reflecting, radiation-absorbing, radiation-scattering and/or radiation-refracting material.

According to at least one embodiment of the method, the at least one component comprises a housing with a housing cavity into which a chip is inserted. The functional material then covers the housing at least in places. The chip may in turn be an optoelectronic semiconductor chip. The functional material can be an optically functional material. Furthermore, it is possible that the functional material is in particular a sealing material, which seals the housing in places, for example, and provides corrosion protection for at least one component of the optoelectronic device.

According to at least one embodiment of the method, the cavity of the housing is confined by at least one inclined side face and the functional material covers the at least one inclined side face in places. The at least one side face extends, for example, inclined to a main extension plane of the source carrier. For example, it is possible for the functional material to cover the side face as a layer of uniform thickness. Such a layer of functional material can be applied to inclined side faces with a particularly precise fit by means of the method described herein.

According to at least one embodiment of the method, the at least one component comprises a chip, wherein the functional material covers the chip in places. For example, the chip is an optoelectronic semiconductor chip. The functional material can then, for example, be a radiation-converting material which is configured to convert primary radiation emitted by the chip from a first wavelength range into secondary radiation from a second wavelength range during operation.

According to at least one embodiment, the functional material on the chip provides adhesion between the chip and the cover body. In this case, the functional material may, for example, be an adhesive that attaches the cover body to the chip in a substance-to-substance manner.

In the following, the method described herein is illustrated in more detail with reference to exemplary embodiments and the associated figures.

### BRIEF DESCRIPTION OF THE DRAWINGS

On the basis of FIG. 1 an exemplary embodiment of a method described herein is illustrated in more detail by means of a schematic sectional view;

FIGS. 2, 3, 4A, 5, 6, 7 show optoelectronic components produced using exemplary embodiments of the methods described herein; and

FIG. 4B illustrates another exemplary embodiment of a method described herein.

### DETAILED DESCRIPTION OF ILLUSTRATIVE EMBODIMENTS

On the basis of the schematic sectional view of FIG. 1 an exemplary embodiment of a method described herein is illustrated in more detail.

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

In the method, at least one component 1 of an optoelectronic device is provided. The component may be, for example, an optoelectronic semiconductor chip, a connection carrier, a housing, a potting or another component of an optoelectronic assembly.

The component 1 can, for example, be applied to an auxiliary carrier 100. The auxiliary carrier 100 can be, for example, a rigid plate or a film. In particular, the method described herein can also be carried out in a roll-to-roll method, wherein a plurality of the at least one components 1 is arranged on the auxiliary carrier 100.

A source carrier 2 is arranged above the components 1, which is formed, for example, with a material that is permeable to the laser radiation 5, which may comprise a glass or a plastic, for example. A layer of functional material 3 is applied to the auxiliary carrier 2 directly or via the separating layer 4. By irradiation with the laser beam 5, a part 31 of the functional material 3 is detached and transferred to the component 1 in this way.

The laser beam 5 can be operated pulsed or continuous. Additional optics can be used to widen the laser beam and to adapt the cross-section of the laser beam 5 to the size of the parts 31. Alternatively or additionally, it is possible to scan the part 31 of the functional material that is to be transferred.

In the exemplary embodiment of FIG. 1, a gap is arranged between the at least one component 1 and the functional material. For example, the functional material and the at least one component are arranged at a distance of at least 1 μm and/or at most 1500 μm from each other. Alternatively, it is possible that, in particular for solid and/or bistable functional materials, there is direct contact between the at least one component and the functional material 3.

The separating material 4 can, for example, be a material that can be converted in places into the liquid or gaseous phase by irradiation with the laser beam 5, which makes it possible to separate the regions 31 in a targeted manner. The use of a separating material 4 has the advantage that there is no thermal or optical degradation in the functional material 3 to be transferred and, in particular, materials that are not suitable for absorbing the laser radiation 5 can also be transferred. The separating material 4 can increase the shape accuracy for liquid or pasty layers of functional material 3 or discrete but non-solid elements of the functional material 3. In this way, the use of a separating material 4 enables the application of discrete elements to the at least one component 1.

The functional material 3 can, for example, be a radiation-reflecting material which can, for example, be formed from silicone with a filling of titanium dioxide particles. It can also be a radiation-absorbing material, which can be formed from silicone with black fillers, for example. Furthermore, the functional material 3 can be a transparent, clear silicone that is radiation-refracting. Furthermore, the functional material may be a luminescence conversion material, for example in the form of particles or particulates in a matrix material, which may also be silicone, for example.

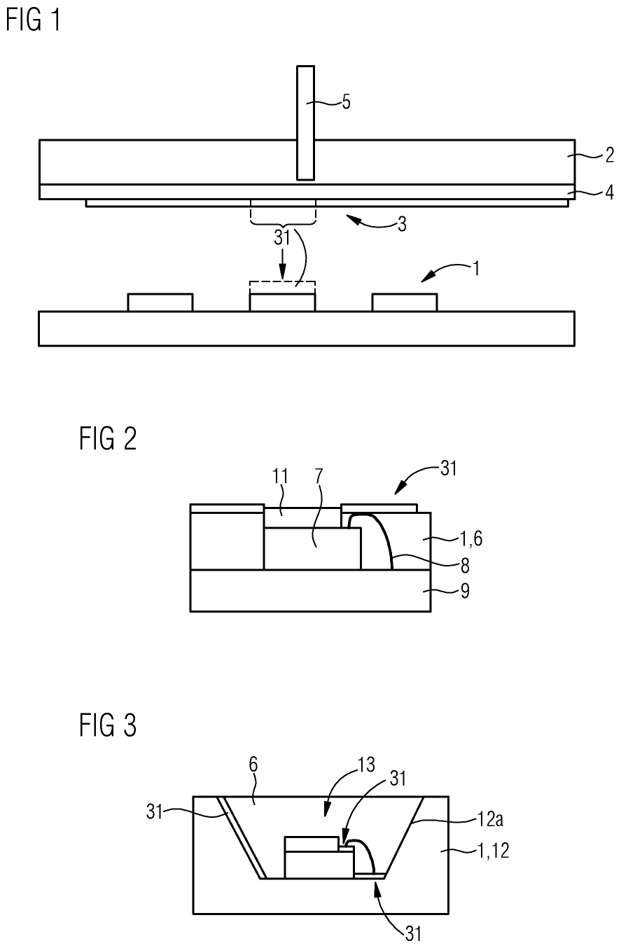

The schematic sectional view in FIG. 2 shows an optoelectronic assembly that can be manufactured by means of an embodiment of a method described herein. In this exemplary embodiment, the at least one component is formed by a potting 6 which laterally surrounds a chip 7. The chip 7 is, for example, a light-emitting diode chip that is connected to a connection carrier 9 via a bonding wire 8. The potting 6 covers side faces of the chip as well as an upper face facing away from the connection carrier 9 in places. The bonding wire 8 can be arranged completely in the potting 6.

For example, the potting 6 can be a potting formed with a plastic material such as silicone and/or epoxy resin. To adjust optical properties, the functional material 31 is applied to the upper face of the potting 6 by means of the method described herein. For example, the functional material 31 surrounds a cover body 11 on the upper face of the chip. The potting 6 can be formed radiation-reflecting and can be formed, for example, with a plastic material filled with white particles.

The functional material 31 can be formed radiation-reflecting or radiation-absorbing. For example, the functional material 31 is a black coating that increases the contrast between the semiconductor chip and the environment.

The functional material 31 and the potting 6 may comprise the same matrix material, which increases adhesion between the potting 6 and the functional material 3. The cover body 11 may, for example, be clear, may be formed as a lens or may comprise a luminescence conversion material.

In the exemplary embodiment of FIG. 3, functional material 31 is applied to various components of the optoelectronic assembly by means of the method described herein. The different functional materials 31 may be different materials with different properties. The optoelectronic assembly produced in this way comprises a housing 12 with a cavity 13 into which the semiconductor chip 7 is inserted.

The chip 7 represents a component to which a functional material 31 is applied by means of the method described herein, for example to a reflective or absorbing region of the chip such as a bond pad. Furthermore, the functional material 31 can be applied to inclined side faces 12a of the housing 12. Here, for example, the functional material 31 can be a paste-like material that is applied as a thin layer with high local accuracy and at the same time with a gap that is larger than 1 mm. For example, the functional material 31 is a radiation-reflecting material. In the same way, the functional material 31 can also be applied to a bottom surface of the cavity 13. This functional material can also be a radiation-reflecting material that covers radiation-scattering or absorbing regions on the bottom surface of the cavity.

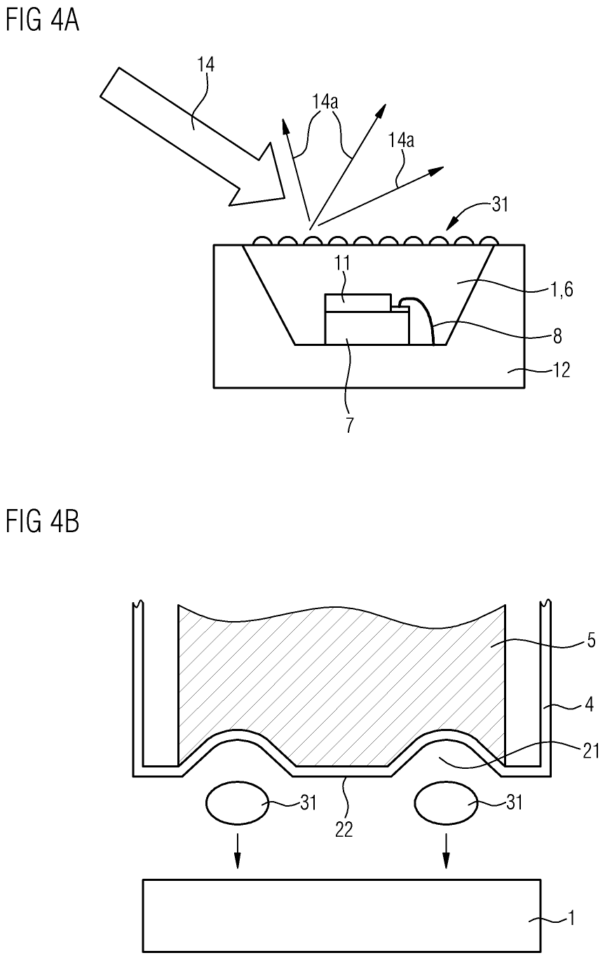

In connection with the schematic sectional view of FIG. 4A, an exemplary embodiment is shown in which a potting 6 surrounding a semiconductor chip 7 forms the component 1 to which the functional material 31 is applied. The functional material 31 can be microstructures that comprise a lateral extension in the micrometer range and have an aspect ratio of >1. For example, radiation-scattering structures can be applied to the outside of a potting 6 in this way, which serve to reduce specular reflection of sunlight or other ambient light. The functional material 31 can thereby be a radiation-scattering material.

In connection with the schematic sectional view of FIG. 4B, an exemplary embodiment of a method described herein is illustrated in more detail, with which structures, such as those shown in FIG. 4A or in FIG. 5, can be transferred to the at least one component 1. In this exemplary embodiment, the source carrier 2 comprises cavities 21 which are filled with parts of the functional material 31. Regions 22 between the cavities 21 are free of the functional material 3. A separating layer 4 may be arranged between the source carrier and the functional material 3.

By means of an expanded laser beam 5, it is possible for several parts 31 of the functional material 3 to be detached from the cavities at the same time and transferred in this way to the at least one component 1.

In connection with FIG. 5, a further exemplary embodiment is shown which can be produced, for example, using the exemplary embodiment of the method shown in connection with FIG. 4B. In this exemplary embodiment, outcoupling structures are applied, for example, to a cover body 11 and to the outer surface of a potting 6, each of which form components for the method described herein. The outcoupling structures can, for example, be formed with a radiation-scattering and a radiation-refracting material and increase the probability of light escaping from the optoelectronic component.

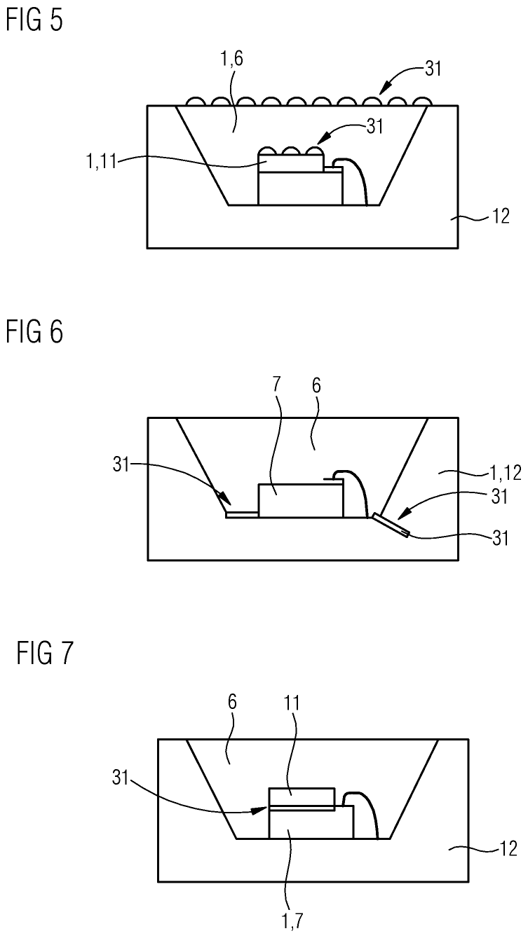

In connection with FIG. 6, an exemplary embodiment of an optoelectronic component is described on the basis of a schematic sectional view, which can be produced by means of an exemplary embodiment of a method described herein. In this exemplary embodiment, for example, parts 31 of the functional material 3 are applied to the housing 12, which forms the component 1. The functional material 3 may, for example, be a sealing material which can be placed in the housing with high lateral accuracy and acts there, for example, against an ingress of atmospheric gases and/or moisture from outside.

In connection with FIG. 7, an optoelectronic component is described on the basis of a schematic sectional view, which can be produced using an exemplary embodiment of a method described herein. Here, the part 31 of the functional material 3 is an adhesive that bonds a cover body 11 to a chip 7 of the optoelectronic assembly. The functional material 3 can then be, in particular, a radiation-transmissive adhesive which is suitable, for example, for attaching a cover body, which is formed as a luminescence conversion element, to the chip. By means of the method described herein, such an adhesive can be applied with a more precise fit than by punching and/or jetting. Furthermore, very small volumes of adhesive can be applied, which is not possible with conventional methods.

The invention is not limited to the exemplary embodiments by the description thereof. Rather, the invention includes any new feature as well as any combination of features, which includes in particular any combination of features in the patent claims, even if this feature or combination itself is not explicitly stated in the patent claims or exemplary embodiments.

1.-13. (canceled)

14. A method for producing an optoelectronic assembly, the method comprising:
providing at least one component of the optoelectronic assembly;
providing a source carrier with a functional material on a lower face of the source carrier facing the at least one component;
detaching a part of the functional material by irradiation via a laser beam through an upper face of the source carrier facing away from the at least one component;
attaching the detached part of the functional material to a side of the at least one component facing the source carrier; and
completing the optoelectronic assembly,
wherein the source carrier comprises cavities, each cavity being filled with the functional material.

15. The method according to claim 14, wherein a separating material, which is irradiated by the laser beam, is arranged between the source carrier and the functional material.

16. The method according to claim 14, wherein the functional material is present as layer or as layer sequence comprising a main extension plane running parallel to a main extension plane of the source carrier.

17. The method according to claim 14, wherein regions between the cavities on the lower face of the source carrier facing the at least one component are free of the functional material.

18. The method according to claim 17, wherein the functional material is in direct contact with the at least one component during detaching.

19. The method according to claim 14, wherein the functional material and the at least one component are arranged at a distance between at least 1 μm and at most 1500 μm, inclusive, from each other.

20. The method according to claim 14, wherein the at least one component comprises a potting surrounding a chip, and wherein the functional material covers the potting in places.

21. The method according to claim 14, wherein the at least one component comprises a housing with a housing cavity into which a chip is inserted, and wherein the functional material covers the housing in places.

22. The method according to claim 21, wherein the housing cavity is confined by at least one inclined side face, and wherein the functional material covers the at least one inclined side face in places.

23. The method according to claim 14, wherein the at least one component comprises a chip, and wherein the functional material covers the chip in places.

24. The method according to claim 23, wherein the functional material provides adhesion between the chip and a cover body.

25. The method according to claim 14, wherein the functional material comprises at least one of the following materials: a radiation reflecting material, a radiation absorbing material, a radiation scattering material, a radiation refracting material, a luminescence conversion material, a sealing material, or an adhesive.

26. A method for producing an optoelectronic assembly, the method comprising:
providing at least one component of the optoelectronic assembly;
providing a source carrier with a functional material on a lower face of the source carrier facing the at least one component;
detaching a part of the functional material by irradiation via a laser beam through an upper face of the source carrier facing away from the at least one component;
attaching the detached part of the functional material to a side of the at least one component facing the source carrier; and
completing the optoelectronic assembly,
wherein the at least one component comprises a potting surrounding a chip, and
wherein the functional material covers the potting in places.

27. The method according to claim 26, wherein the source carrier comprises cavities which are each filled with the functional material.

28. A method for producing an optoelectronic assembly, the method comprising:
providing at least one component of the optoelectronic assembly;
providing a source carrier with a functional material on a lower face of the source carrier facing the at least one component;
detaching a part of the functional material by irradiation via a laser beam through an upper face of the source carrier facing away from the at least one component;
attaching the detached part of the functional material to a side of the at least one component facing the source carrier; and
completing the optoelectronic assembly,
wherein the at least one component comprises a chip and a potting surrounding the chip,
wherein the functional material covers the chip in places and the functional material provides adhesion between the chip and a cover body.

29. The method according to claim 28, wherein the source carrier comprises cavities, each cavity being filled with the functional material.
